(19) United States
(12) Patent Application Publication
(10) Pub. No.: US 2002/0045105 A1
(43) Pub. Date: Apr. 18, 2002

(54) High quality lithographic processing

(76) Inventors: David R. Brown, Meridianville, AL (US); Gregg T. Borek, Huntsville, AL (US); Randy Lindsey, Huntsville, AL (US); Pete S. Erbach, Harvest, AL (US)

Correspondence Address: BIRCH STEWART KOLASCH & BIRCH, PO BOX 747, FALLS CHURCH, VA, 22040-0747, US

(21) Appl. No.: 09/895,152

(22) Filed: Jul. 2, 2001

Related U.S. Application Data
(60) Provisional application No. 60/216,359, filed on Jul. 5, 2000.

(51) Int. Cl. G03F 9/00

(52) U.S. Cl. 430/5; 430/312

(57) ABSTRACT

Lithographic processes utilized for fabrication of micro-machines have been heretofore been plagued by stitching errors and errors arising from the roughness of the surface of the photosensitve material. These errors can be minimized by the utilization of multi-pass exposure techniques to minimize the stitching errors. The surface roughness errors are minimized by a thermal treatment of the surface of the photosensitive material that leaves the bulk of the photosensitve material undisturbed.

### FIELD OF THE INVENTION

Multi-pass patterning reduces stitching error and melt processing improves the surface quality of the photosensitive material produced using a gray scale or analog lithography process.

### BACKGROUND OF THE INVENTION

There is a need in a variety of micro-structures such as micro-optics or MEMS (micro-electro-mechanical systems) for small structures, i.e., microstructures or micromachines, that are curved or non-linear in a variety of structures in a direction orthogonal to the direction of the substrate. These small curved structures are less than 100 μm in size, and curved structures of this magnitude have proved difficult to achieve through traditional photolithographic and etching processes. These curved structures would be desirably used to produce components such as turbine rotors and micro-lenses necessary to form micro-scale or meso-scale machines in silicon or other desirable materials. Micromachines also include “microfluidic” devices, or mini-refrigerators inside PCs that squelch internal heat, microrelays, optical attenuators, optical shutters, photonic switches, accelerometers, and gyroscopes. High quality lithographic processing is not restricted to micro-machines, but is also used to form micro-structures such as micro-optics or micro-lenses.

Gray scale lithography process refers to a one step lithography process that produces complex 3-dimensional surface topography in photosensitive materials.

Standard gray scale techniques allow the etching of shallow curved surfaces of a magnitude of less than 100 μm using an etch method such as ion milling with argon. Standard gray scale techniques require thick layers of photoresist which are usually approximately 1-50 μm deep. Gray scale photolithography uses an exposure mask, which can be constructed with a plurality of precisely located and sized light transmitting openings. This technology is typified by using a chrome mask having small openings. The openings are formed with sufficiently small specific opening sizes and are located at a sufficiently large number of specific locations which correlate to related locations on the desired object, to allow an image of the designed object to be produced in a photoresist material.

Gray scale photolithography typified by U.S. Pat. Nos. 5,482,800 and 5,310,623 to Gal uses a single pixel exposure mask subdivided into subpixels. Each subpixel is in turn subdivided into gray scale resolution elements. According to Gal, a typical pixel can be about 2-4 μm on each side, each subpixel can be about 1-3 μm on each side, and each gray scale resolution element can be 0.2 μm on each side. The exposing light is uv light of about 0.365-0.436 μm wavelength. According to Gal, the resolution elements can be arranged in groups so as to enable a full wavelength of the uv light to pass through an opening formed by the aligned resolution elements. Infrared light and uv light wavelengths are used with different types of gray scales.

Patterning the photoresist to form a photomask layer can be performed using a single gray scale mask. Alternatively, patterning the photoresist to produce a variable thickness photomask layer can be accomplished by exposing with 2 gray scale masks.

By using an appropriate pattern, an exposure in a photoresist material can be created which will cause the height of the processed photoresist material to replicate the height of the desired workpiece. The exposed photoresist can then be processed by developing using known methods to produce an impression of the desired pattern in the developed photoresist. Alternatively, the patterned photoresist itself can be the final product.

The image is produced by exposing the photoresist material to light of a selected wavelength through the gray scale mask, transmitted through openings in the exposure mask for a selected time period. The light is usually ultraviolet light. The exposed photoresist material is subsequently processed to procure the desired object on a substrate material using an etching method such as ICP-machining or RIE/ICP-machining.

There are gray scale mask technologies, including the half tone process, the modulated exposure masking technique and Canyon Material's High Energy Beam Sensitive (HEBS) glass. These techniques partially expose a photosensitive material to achieve a desired structure. Photosensitive materials include, but are not limited to, photoresist and PMMA (polymethyl methacrylate) materials. When using HEBS, the glass itself is photosensitive.

High Energy Beam Sensitive (HEBS) glass is a one step fabrication of a gray level mask. The exposure of this gray level mask is done using a e-beam writing tool. The e-beam writing tool software is used to support mask making and direct write-on resist approaches for the fabrication of diffractive optical elements (DOEs). The so-generated gray level mask is usable in an optical exposure tool (e.g., a G-line stepper, or a contact printer) to mass fabricate resist profiles.

Using the HEBS-glass gray level mask fabrication and a following optical exposure, alignment errors are possibly avoided, since the mask is written in a single step using different electron beam dosages to generate gray levels. Instead of fabricating of a set of five binary masks with all the involved resist processing and wet etching, only a single writing step without any resist processing is used. This single mask then contains all the necessary information previously contained in a set of five binary chrome masks.

After the HEBS gray level mask is fabricated a series of single exposures in a step-and-repeat system can generate hundreds of DOEs on the same wafer. This wafer can then be processed to transfer the DOE structure of a large number of different elements into the substrate. Since the complete DOE structure is transferred into the substrate there is no need for a resist stripping step after the etching process. After dicing the wafer, many of monolithic multilevel DOEs have been generated.

There are at least two main sources of errors that plague the surface profile of structures, in photosensitive materials, resulting from a gray scale or analog lithography process.

The first source of error arises from general roughness in the surface of the photosensitive material. This error may be caused by the slight variations in the dose of the writing tool, usually an electron beam (e-beam) or laser. In the case of the half tone process, the chosen pixel shape scheme may cause this error. The period of oscillation for the general roughness error is typically on the order of 10 microns.

The second source error is the stitching error; it is geometric and is induced by slight variations in the positioning and size of the writing tool. Stitching error is due to slight inaccuracies of the stage and field of the writing tool. The stage of the writing tool refers to the horizontal sweep, wherein slight variation in the positioning of the horizontal line results in stitching error. The field refers to the width of the writing line, wherein variation in the width of the writing line also results in stitching error. The stitching error is of low frequency period and manifests itself in the slight vertical lines in the surface

The stitching error is illustrated in the intensity map of the conventional art anamorphic lens depicted in FIG. 1. FIG. 1 shows that surface discontinuities in the surface contours are plainly evident.

The general roughness and stitching errors also occur in direct photosensitive material writing applications, wherein a mask is not used. The general roughness error occurs because the direct writing tool (e.g., e-beam or laser) may be prone to writing dose variations. The stitching error occurs because the direct writing tool may be prone to geometric variations. The stitching errors also occur in binary lithographic process applications wherein a mask is used.

As has been shown, there are at least two major problems, general roughness and stitching errors, that hamper the implementation of gray-scale and analog photolithography process for the production of the small three dimensional structures required to fabricate micro-machines and micro-optics. The present invention solves these problems by using thermal treatment and multi-pass exposure.

It is to be understood that both the foregoing general description and the following detailed description are exemplary and explanatory and are intended to provide further explanation of the invention as claimed.

### SUMMARY OF THE INVENTION

The invention, in part, pertains to a method for minimizing lithographic errors arising from stitching errors.

The invention, in part, pertains to a method for minimizing lithographic errors arising from the surface roughness of a photosensitive material used in the lithographic process.

The invenion, in part, pertains to an optimized photolithographic method suitable for fabricating micro-machines and micro-optics.

The invention, in part, pertains to a lithographic method of performing a plurality of passes to write a specific structure onto a photosensitive material, exposing the photosensitive material, and melting at least a top layer portion of the photosensitive material.

The invention, in part, pertains to a mask formed by providing a photosensitive material, performing at least one pass to write a pattern onto the photosensitive material, and developing the photosensitive material.

The invention, in part, pertains to microstructures and a method for lithographic processing for the formation of microstructures which includes providing a substrate, applying a photosensitive material over the substrate, performing at least one pass to write a pattern of a specific structure onto the photosensitive material, whereby stitching error is reduced, melting at least a portion of the photosensitive material, whereby general roughness error is reduced, developing the pattern, and removing remaining photosensitive material.

The invention, in part, pertains to a micro-structure or micro-optice device formed by a lithographic method of performing a plurality of passes to write a specific structure onto a photosensitive material, exposing the photosensitive material using the mask, and melting a top layer of a photosensitive material, wherein the device can be a turbine rotor, a micro-lens, a microfluidic device, a microrelay, an optical attenuator, an optical shutter, a photonic switch, an accelerometer or a gyroscope.

### BRIEF DESCRIPTION OF THE DRAWINGS

The accompanying drawings are included to provide a further understanding of the invention. The drawings illustrate embodiments of the invention and together with the description serve to explain the principles of the embodiments of the invention.

FIG. 1 depicts an intensity map of a conventional art anamorphic lens.

FIG. 2 depicts an intensity map of an anamorphic lens produced according to the invention.

FIG. 3 depicts a surface profile of a conventional art anamorphic lens of FIG. 1.

FIG. 4 depicts a surface profile of the anamorphic lens produced according to the invention of FIG. 2.

FIG. 5 depicts the partial melting of a photosensitive material according to the invention.

### DETAILED DESCRIPTION

Advantages of the present invention will become more apparent from the detailed description given herein. However, it should be understood that the detailed description and specific examples, while indicating preferred embodiments of the invention, are given by way of illustration only, since various changes and modification within the spirit and scope of the invention will become apparent to those skilled in the art form this detailed description.

One solution for fixing the general roughness error in accordance with the teachings of the present application is a melting process. The preferred goal in this solution is to melt only the top layer of the photosensitive material and allow surface tension to pull the roughness out of the surface.

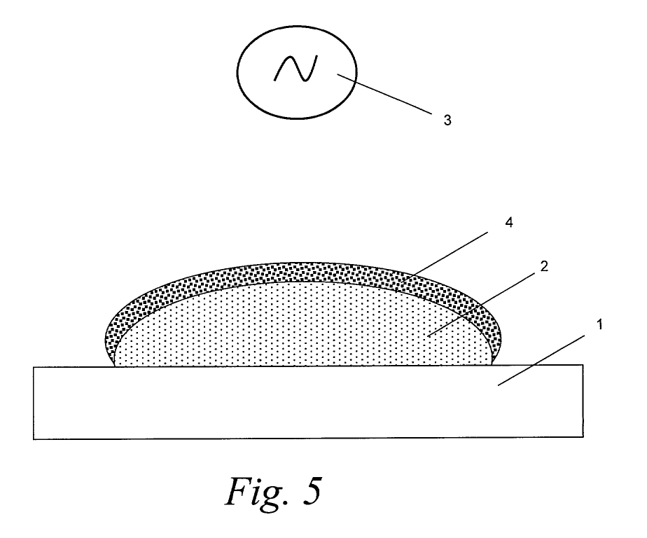

FIG. 5 depicts the melting process. Over a substrate 1 is deposed a structure 2 composed of a photosensitive material such as a photoresist. A heat source 3 applies heat to the structure 2 so that a portion of the structure 4 melts while leaving the bulk of the structure 2 in an unmelted state. Upon cooling the photosensitive material resolidifies to provide a structure having a smooth surface.

There are several techniques to accomplish the heating process solution; the appropriate technique may depend on the initial surface structure. The different techniques include at least (1) baking the photosensitive material for a specific amount of time; (2) placing the wafer upside down so that the photosensitive material is a short distance, e.g. a few millimeters or greater, from a heat source such as a hot plate, thermoelectric element, infrared lamp or a thermal bath; (3) using a heat gun to blow hot air onto the photosensitive surface; (4) flowing a hot liquid over the surface of the photosensitive material; and (5) flowing a hot solvent vapor over the surface of the photosensitive material. The objective in practicing this solution is to not melt or reflow the bulk of the photosensitive material but rather to smooth surface irregularities without changing surface contour.

The temperature and heating time depends on the depth and aspect ratio of the structure being heated. Higher temperatures are inappropriate for shallow structures, and lower temperatures are used for thicker structures. For example, a temperature of about 125° C. for a time of about 10-30 minutes is used for a shallow structure having a depth of about 8 μm. As another example, a temperature of about 95° C. for a time of about 15 minutes is used for a thicker structure having a depth of about 15-20 μm.

Another factor affecting the time and temperature of the heating is the material of the photosensitive material. For example, a polyamide photoresist will require a higher time and temperature than other types of photoresists. Examples of the polyamide photoresist include but are not resitricted to PA6T (polyhexamethylenediamine terephthalate), PA66 (polyhexamethylenediamine adipate) and PA46 (polytetramethylenediamine adipate).

The temperature bake according to technique (1) may preferably be in the range of about 120-170° C. for a duration of about 30 seconds to about 1 hour. Preferred temperature ranges for this embodiment include about 120-130°C., about 130-140°C., about 140-150°C., about 150-160° C. and about 160-170°C. Preferred baking times include about 30 seconds to 1 minute, about 1 minute to about 1.5 minutes, about 1.5 minutes to about 2 minutes, about 2 minutes to about 2.5 minutes, about 2.5 minutes to about 3 minutes, about 3 minutes to about 3.5 minutes, about 3.5 minutes to about 4 minutes, about 4 minutes to about 4.5 minutes, about 4.5 minutes to about 5 minutes, about 5 minutes to 10 minutes, about 10 minutes to 20 minutes,. about 20 minutes to 30 minutes, about 30 minutes to 40 minutes, about 40 minutes to about 50 minutes and about 50 minutes to about 1 hour.

Alternatively, the bake of technique 1 can be performed at about 60-120° C. for about 30 minutes or longer. In this embodiment, the preferred temperature ranges include about 60-70°C., about 70-80°C., about 80-90°C., about 90-100°C., about 100-110°C., and about 110-120°C. The baking time at these lower temperatures is preferably, but is not restricted to about 24 hours or less. Preferred baking times include about 30 minutes to about 1 hour, about 1 hour to about 2 hours, about 2 hours to about 3 hours, about 3 hours to about 4 hours, about 4 hours to about 5 hours, about 5 hours to about 6 hours, about 6 hours to about 7 hours, about 7 hours to about 8 hours, about 8 hours to about 9 hours, about 9 hours to about 10 hours, about 10 hours to about 11 hours, about 11 hours to about 12 hours, about 12 hours to about 13 hours, about 13 hours to about 14 hours, about 14 hours to about 15 hours, about 15 hours to about 16 hours, about 16 hours to about 17 hours, about 17 hours to about 18 hours, about 18 hours to about 19 hours, about 19 hours to about 20 hours, about 20 hours to about 21 hours, , about 21 hours to about 22 hours, about 22 hours to about 23 hours, and about 23 hours to about 24 hours.

According to technique (1), preferably the temperature bake may be 150° C. for less than 1 minute or may be 70° C. for more than 30 minutes. The principles of the invention according to technique (1) may be practiced using temperature and duration ranges appropriate to the used specific photosensitive material and desired resulting structure.

Since the bake temperature and time are dependent on a range of variables including the type of photosensitive material and the depth and geometry of the photosensitive material, there can be an overlap of the preferred temperatures and times of the heating. As a result, preferred temperature and time ranges can be wherein the temperature is about 80-170° C. and the time is up to about 1 hour, or wherein the temperature is about 60-90° C. and the time is greater to or equal to about 30 minutes.

The bake can be performed in the ambient atmosphere, i.e., air. However, the bake can also be performed in an inert gas such as nitrogen, argon, helium or neon.

Technique (2) entails exposing the photosensitive material's surface to a hot plate. Technique (3) entails using a heat gun to blow hot air onto the photoresist surface. Technique (4) entails flowing a hot liquid over the surface of the photosensitive material. Technique (5) entails flowing a hot solvent vapor over the surface of the photosensitive material. The time and temperature intervals used for technique (1) are also applicable to techniques (2) through (5).

The heat-treating process preferably liquefies the surface of the melt while leaving the bulk of the photosensitive material solidified. The melt ranges can include about 10-20% of the photosensitive material's bulk, about 20-30% of the photosensitive material's bulk, about 30-40% of the photosensitive material's bulk and about 40-50% of the photosensitive material's bulk. Preferably, sufficient photosensitive material is melted to cover the depth corresponding to the surface roughness of the photosensitive material. This preferable depth is expressed as the root mean square of the surface roughness.

Although partial liquefaction of the photosensitive material is preferred, the heat treating method is also effective when the entire bulk of the photosensitive material is liquefied. This is especially true when the photosensitive material is present in the form of a thin film, which is highly sensitive to effects arising from intimate contact of the photosensitive material with the substrate.

The elimination of stitching error by multiple passes is effective in at least two separate embodiments of the invention.

One embodiment of the invention uses multiple passes to eliminate stitching error when forming the mask. Multiple pass writing is used to pattern the mask, which can be a gray scale mask. When forming the mask, no heat treating is used to reduce the surface roughness.

In a second embodiment of the invention, stitching error and exposure non-uniformity in the writing process are alleviated by using a multiple pass writing technique. The process is to write the desired pattern many times with partial dosage. This writing can be performed with a mask formed using multiple passes or alternatively with a mask that has been formed conventionally. The effect of the multiple writes results in the final desired structure. The total dose of writing (total of doses of the multiple writings) may be somewhat greater than the dose necessary for a one step writing according to the conventional art.

Using multiple passes according to the invention, reduces the stitching errors due to the random propagation of errors. During each pass the stage and field errors will be randomly different then the during other passes. This effectively minimizes the error of any given pass by averaging the errors of all of the passes thus producing a more uniform gray tone mask.

The multiple passes may be done in such a way to maximize this averaging effect. One such technique for maximizing averaging effect is to purposely shift each pass by some vary small distance (or offset) such that no two passes write along the same path. Generally, about 2 to about 8 passes are sufficient to attain the averaging effect. Frequently, the averaging effect can be achieved using about 2 to 4 passes. A greater number of passes can also be used. However, a large number of passes will not appreciably improve on the averaging effect achieved by a lower number of passes.

A wide type of energy sources can be used for multiple pass writing. These energy sources include laser, uv, electron beam, infrared, visible and x-ray sources.

The principles of the invention disclosed herein as applied to gray scale lithography process may also be applied to a binary lithography process mainly but not limited to a direct resist scanning on a binary or multiple mask. The techniques of the present application may also be applied to direct writing, i.e., ablating processes.

An order for practicing the principles of the invention is (1) fixing stitching error by multiple pass writing (either in writing the mask for gray scale or binary lithographies, or writing directly to the photosensitive material); (2) exposing the photosensitive material using the mask (present for gray scale and binary lithographies, but possibly not present for direct photosensitive material writing); and (3) fixing the general roughness error by heating the top layer of the photosensitive material (present for all three lithographies).

The lithography process of the invention need not be practiced using both the step of multiple pass writing and the step of heating the top layer. Both the multiple pass writing and the heating steps can be performed separately, without the other step, to obtain a superior lithographic process. Preferably, the lithographic process is performed using both the steps of multiple pass writing and heating.

A typical sequence of forming a microstructure on a substrate accroding to the invention would be to spin down a lyer of resist on the substrate, to expose the substrate (possibly using multiple passes) with or without a mask, develop the photosensitive material, heat treat, etch the substrate and remove the photosensitive material.

Alternatively, the photosensitive material itself is the final product. For example, the end product is a master formed from photoresist. In this case, the process is performed without the etching step.

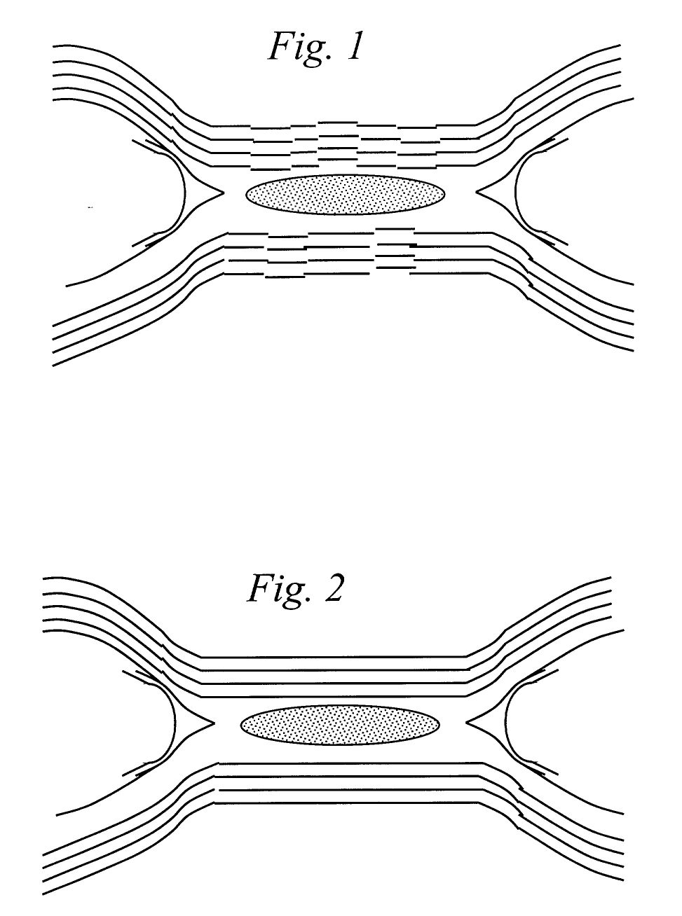

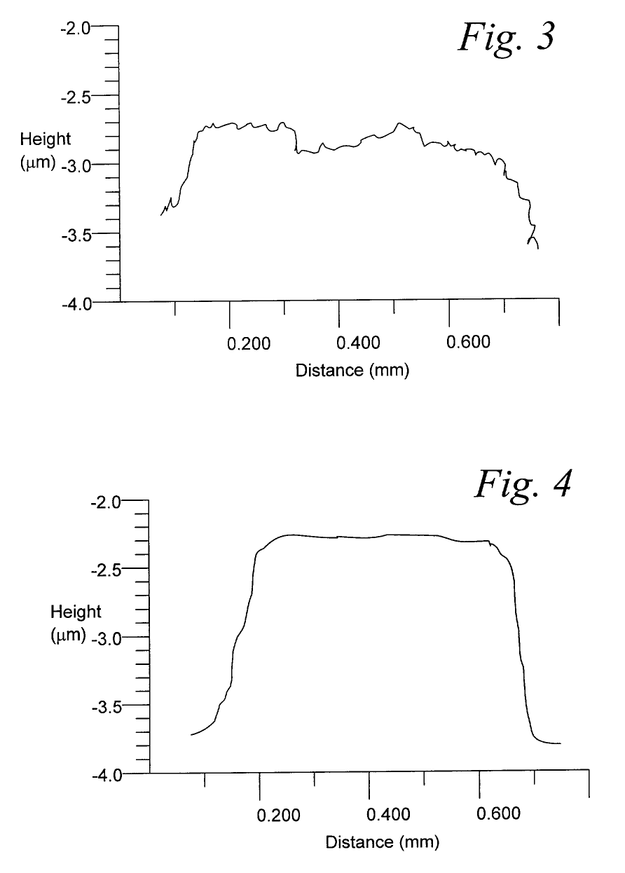

FIGS. 1 and 3, when compared to FIGS. 2 and 4, shows the improved quality of the surface of a photosensitive produced by reducing, according to the invention described herein, the general roughness and stitching errors. The solutions to the general roughness and stitching errors may be applied to the variety of different photosensitive materials including, but not limited to photoresist and PMMA (polymethyl methacrylate) materials.

The photosensitive material can also be an photosensitive emulsion such as a photographic emulsion plate. A ‘black resist’, i.e., a photoresist doped with a dye which affects the sensitivity to certain wavelengths, can also be used. The photosensitive material can also be a positive or negative photosensitive glass such as HEBS glass.

The photosensitive material can be a photoresist. The photoresist can be a positive or negative photoresist. The positive photoresist material can be a polyamide, polybutene-1-sulfone or novalac (phenyl-formaldehyde resin). The novalac resin can contain a diazonaphthoquinone sensitizer or other type of sensitizer. The negative photoresist material can be a polyimide. Epoxy based negative resists have been used in MEMS processing. A preferred photoresist is a positive novalac photoresist. The specific type of photoresist is selected for, among other characteristics, the desired depth of the photoresist layer. The photoresist layer can be be of any thickness, but a photoresist thickness of from about 1 μm to about 50 μm is preferred.

The substrate material is preferably silicon. However, the substrate may be selected from any number of materials, which can be silicon, GaAs, plastic, glass, quartz or metals such Cu, Al and Ge.

The process of the invention can be used in conjunction with semiconductor manufacturing technologies known to the conventional art. These technologies include but are not limited to applying photoresist, patterning, etching with chemical etchants such as HF, plasma etch, ion etch, oxidizing, doping, stripping, nitriding, passivating, CVD, MOCVD, PECVD and MBE.

Results comparing the conventional art anamorphic lens and an anamorphic lens according to the invention can be observed by contrasting FIGS. 1 and 3, pertaining to a conventional art anamorphic lens with FIGS. 2 and 4, pertaining to an anamorphic lens produced according to the process of the invention. FIG. 1 and FIG. 2 show comparative intensity maps of anamorphic lenses according to the conventional art and the invention. FIG. 3 and FIG. 4 show comparative surface profiles of anamorphic lenses according to the conventional art and the invention. The anamorphic lens of the invention shows unexpected and markedly improved oblique contours (not shown), a smoother intensity map and a higher and less variable surface profile when compared to the conventional art anamorphic lens.

The marked improvement in the stitching error is illustrated by comparing a depiction of the intensity map of the conventional art anamorphic lens in FIG. 1 with a depiction of the intensity map of an anamorphic lens of the invention of FIG. 2. FIG. 1 clearly shows the contour discontinuities arising from the stitching error. In contrast, the intensity map of the invention depicted in FIG. 2 is free from discontinuities and exposure non-uniformity arising from stitching errors.

The improvement in the surface smoothness acheived by the invention can be observed by comparing the surface profile of a conventional art anamorphic lens depicted in FIG. 3 with a surface profile of the anamorphic lens produced according to the invention depicted in FIG. 4. The conventional art anamorphic lens of FIG. 3 has a lower profile and a rough surface. The anamorphic lens of the invention of FIG. 4 has a higher profile and a distinctly smoother surface than the conventional art lens.

It is to be understood that the foregoing descriptions and specific embodiments shown herein are merely illustrative of the best mode of the invention and the principles thereof, and that modifications and additions may be easily made by those skilled in the art without departing for the spirit and scope of the invention, which is therefore understood to be limited only by the scope of the appended claims.

We claim:

1. A method for forming a mask, which comprises:
providing a photosensitive material;
performing at least one pass to write a pattern onto the photosensitive material; and
developing the photosensitive material.

2. The method of claim 1, further comprising etching the photosensitive material.

3. The method of claim 1, wherein the photosensitive material is a photoresist, an e-beam resist, a HEBS glass, an emulsion or a black resist.

4. The method of claim 1, wherein there are about 2-8 passes.

5. The method of claim 1, whrein each pass is offset such that no two passes write along the same path.

6. The method of claim 1, wherein the at least one pass is performed using a laser, uv, electron beam, infrared, visible or x-ray source.

7. The method of claim 1, wherein stitching error and exposure non-uniformity is reduced.

8. A method of lithographic processing for the formation of a microstructure, which comprises:
providing a substrate;
applying a photosensitive material over the substrate;
performing at least one pass to write a pattern of a specific structure onto the photosensitive material, whereby stitching error and exposure non-uniformity is reduced;
melting at least a portion of the photosensitive material, whereby general roughness error is reduced;
developing the photosensitive material; and
removing remaining photosensitive material.

9. The method of claim 8, further comprising:
etching the photosensitive material to transfer the microstructure onto the substrate.

10. The method of claim 8, wherein the at least one pass is performed using a mask.

11. The method of claim 10, wherein the mask has been formed using a plurality of passes.

12. The method of claim 8, wherein the step of melting comprises a step of heating the photosensitive material at a temperature for a period of time.

13. The method of claim 12, wherein the temperature is about 80-170° C. and the time is up to about 1 hour.

14. The method of claim 12, wherein the temperature is about 60-90° C. and the time is greater to or equal to about 30 minutes.

15. The method of claim 8, wherein the step of melting comprises placing the photosensitive material upside down near a heat source.

16. The method of claim 14, wherein the heat source comprises a hot plate.

17. The method of claim 8, wherein the step of melting comprises flowing a hot fluid or solvent vapor across the surface of the photosensitive material.

18. The method of claim 8, wherein the method further comprises:
performing gray scale lithography.

19. The method of claim 17, wherein the gray scale lithography process is half tone process.

20. The method of claim 18, wherein the gray scale lithography process is a modulated exposure masking process.

21. The method of claim 8, wherein there are about 2-8 passes.

22. The method of claim 8, wherein each pass is offset such that no two passes write along a same path.

23. A mask, the mask being formed by a process comprising:
providing a photosensitive material;
performing at least one pass to write a pattern onto the photosensitive material; and
developing the photosensitive material.

24. The mask of claim 23, wherein the photosensitive material is a photoresist.

25. The mask of claim 23, wherein there are about 2-8 passes.

26. The mask of claim 23, whrein each pass is offset such that no two passes write along the same path.

27. The mask of claim 23, wherein the process further comprises etching the photosensitive material.

28. The mask of claim 23, wherein stitching error and exposure non-uniformity is reduced.

29. A microstructure, the microstructure being formed by a process comprising:
providing a substrate;
applying a photosensitive material over the substrate;
performing at least one pass to write a pattern of a specific structure onto the photosensitive material, whereby stitching error and exposure non-uniformity is reduced;
melting at least a portion of the photosensitive material, whereby general roughness error is reduced;
developing the photosensitive material; and
removing remaining photosensitive material.

30. The microstructure of claim 29, wherein the at least one pass is performed using a mask.

31. The microstructure of claim 29, wherein the step of melting comprises a step of heating the photosensitive material at a temperature for a period of time.

32. The microstructure of claim 31, wherein the temperature is about 80-170° C. and the time is up to about 1 hour.

33. The microstructure of claim 29, wherein the temperature is about 60-90° C. and the time is greater to or equal to about 30 minutes.

34. The microstructure material of claim 29, wherein the photosensitive material is a photoresist.

35. The microstructure of claim 29, wherein the microstructure is a turbine rotor, a micro-lens, a microfluidic device, a microrelay, an optical attenuator, an optical shutter, a photonic switch, an accelerometer or a gyroscope.
